(19) United States
(12) Patent Application Publication
(10) Pub. No.: US 2015/0104938 A1
(43) Pub. Date: Apr. 16, 2015

(54) METHOD FOR FORMING DAMASCENE OPENING AND APPLICATIONS THEREOF

(71) Applicant: UNITED MICROELECTRONICS CORPORATION, Hsinchu (TW)

(72) Inventors: Yi-Fang TAO, Taichung City (TW); Chang-Hsiao LEE, Tainan City (TW); Yu-Fen WANG, Tainan City (TW); Hsin-Yu CHEN, Nantou County (TW)

(73) Assignee: UNITED MICROELECTRONICS CORPORATION, Hsinchu (TW)

(21) Appl. No.: 14/054,834

(22) Filed: Oct. 16, 2013

(51) Int. Cl. H01L 21/768; H01L 21/033

(52) U.S. Cl. CPC H01L 21/76805; H01L 21/76811; H01L 21/76814; H01L 21/76826; H01L 21/76831; H01L 21/76877; H01L 21/0332
USPC 438/666

(57) ABSTRACT

A method for forming a damascene opening, wherein the method comprises steps as follows: Firstly, a semiconductor structure comprising an inter-metal dielectric (IMD), a first hard mask layer and a second hard mask layer stacked in sequence is provided, wherein the semiconductor structure has at least one trench extending downwards from the second hard mask layer to the IMD. A plasma treatment is then performed to modify a portion of the first hard mask layer exposed from the trench. Subsequently, a wet treatment is performed to remove the second hard mask layer and a portion of the first hard mask layer, wherein the plasma-modified portion of the first patterned hard mask layer has a first removing rate substantially less than a second removing rate of the second hard mask layer in the wet treatment.

### FIELD OF THE INVENTION

The present invention relates to a method for forming a semiconductor device, and more particularly to a method for forming a damascene opening and applications thereof.

### BACKGROUND OF THE INVENTION

As integrated circuits become complex and the feature sizes continue to shrink, it becomes increasingly difficult to form interconnection patterns exhibiting the requisite circuit speed with high dimensional accuracy and reliability. Interconnect technology is constantly challenged to satisfy the ever-increasing requirements for high density and performance associated with ultra large scale integration semiconductor devices.

Damascene interconnect technology is widely used to provide planarized interconnect structures due to the advantages of improving the device reliability and increasing the productivity. Damascene interconnect process typically comprises steps of performing at least one dielectric etching process to form at least one via hole and/or trench in an insulating layer and performing a metal filling process to fill the via hole and/or the trench with metal, such as copper (Cu) or aluminum (Al), to form metal interconnect lines or visas that provide interconnection of integrated circuits in semiconductor device.

However, the damascene interconnect technology still has some drawbacks, for example, Cu seed may deposit overhead around the opening of the trenches or via holes during the metal filling process, so as to adversely affect the metal filling quality and device yield.

Therefore, it is necessary to provide an improved method for fabricating damascene openings and the applications thereof to obviate the drawbacks and problems encountered from the prior art.

### SUMMARY OF THE INVENTION

In accordance with one aspect, the present invention provides a method for forming a damascene opening, wherein the method comprises steps as follows: Firstly, a semiconductor structure comprising an inter-metal dielectric (IMD), a first hard mask layer and a second hard mask layer stacked in sequence is provided, wherein the semiconductor structure has at least one trench extending downwards from the second hard mask layer to the IMD. A plasma treatment is then performed to modify a portion of the first hard mask layer exposed from the trench. Subsequently, a wet treatment is performed to remove the second hard mask layer and a portion of the first hard mask layer, wherein the plasma-modified portion of the first patterned hard mask layer has a first removing rate substantially less than a second removing rate of the second hard mask layer in the wet treatment.

In one embodiment of the present invention, the process for providing the semiconductor structure comprises steps as follows: A conductive layer is firstly formed on a substrate, and a bottom layer is then formed on the conductive layer. Next, the IMD is formed on the bottom layer; a first hard mask layer is formed on the IMD; and the second hard mask layer is formed on the first hard mask layer, wherein the second hard mask layer has at least one trench opening for exposing a portion of the first hard mask layer.

In one embodiment of the present invention, the process for providing the semiconductor structure further comprises steps of forming a photo-resist layer on the second hard mask layer to fill the trench opening; patterning the photo-resist layer to form a via opening aligning to the trench opening, so as to expose a portion of the first hard mask layer; performing a via-etching process to form a via hole passing through the first hard mask layer and the IMD layer, so as to expose a portion of the bottom layer; and performing a trench-etching process using the second hard mask layer as a mask to form the trench and to make the via hole passing through the bottom layer for exposing a portion of the conductive layer.

In one embodiment of the present invention, the first hard mask layer is a titanium (Ti) layer, and the second hard mask layer is a titanium nitride (TiN) layer.

In one embodiment of the present invention, the first hard mask layer has a thickness substantially ranging from 50 angstrom (Å) to 300 Å. In one embodiment of the present invention, the second hard mask layer has a thickness substantially ranging from 100 Å to 300 Å. In one embodiment of the present invention, the first hard mask layer and the second hard mask layer have a total thickness about 300 Å.

In one embodiment of the present invention, the wet treatment comprises steps of using an agent containing heterocyclic compound to remove the second hard mask layer and a portion of the first hard mask layer.

In one embodiment of the present invention, the wet treatment further comprises steps of cleaning the trench and the via hole.

In one embodiment of the present invention, the TiN layer is removed by the agent of the wet treatment with an etching rate ranging from 1 angstrom/minute (Å/min) to 250 Å/min, and the Ti layer is removed by the agent of the wet treatment with an etching rate substantially less than 1 Å/min.

In one embodiment of the present invention, the plasma treatment comprises a reaction gas selected from a group consisting of oxygen (O₂), CHF₃, CH₂F₂, CH₃F, CF₄ and arbitrary combinations thereof.

In one embodiment of the present invention, the reaction gas comprises O₂, and the plasma-modified portion of the first patterned hard mask layer comprises titanium oxide (TiO). In one embodiment of the present invention, the reaction gas comprises CF₄, and the plasma-modified portion of the first patterned hard mask layer comprises titanium fluoride (TiF).

In accordance with another aspect, the present invention provides a method for fabricating a dual damascene structure, wherein the method comprises steps as follows: Firstly, a semiconductor structure comprising a conductive layer, an IMD, a first hard mask layer and a second hard mask layer stacked in sequence is provided, wherein the semiconductor structure has at least one trench extending downwards from the second hard mask layer and passing trough the first hard mask layer and the IMD to expose the conductive layer. A plasma treatment is then performed to modify a portion of the first hard mask layer exposed from the trench. Subsequently, a wet treatment is performed to remove the second hard mask layer and a portion of the first hard mask layer, wherein the plasma-modified portion of the first patterned hard mask layer has a first removing rate substantially less than a second removing rate of the second hard mask layer in the wet treatment. Thereafter, a metal material is filled into the trench in contact with the exposed conductive layer.

In one embodiment of the present invention, the method for fabricating a dual damascene structure further comprises steps of forming a seed layer on sidewalls of the trench and the exposed conductive layer prior to the metal material is filled into the trench.

In accordance with the aforementioned embodiments of the present invention, two hard mask layer stacked in sequence is applied on an IMD to form a damascene opening therein; a plasma treatment is then performed to modify a portion of the underlying hard mask layer that is exposed from the trench; the upper hard mask layer is removed by a wet treatment prior to a subsequent metal filling process; and a damascene interconnect structure is formed after the metal filling process is carried out.

Since, the plasma-modified portion of the underlying hard mask layer has a removing rate substantially less than a removing rate of the upper hard mask layer in the wet treatment, thus after the upper hard mask layer is removed, a rounding profile of the underlying hard mask layer is define at the edge of the damascene opening damascene opening. As a result, the damascene opening may have a flared opening that can prevent Cu seed from depositing overhead around the opening of the damascene opening, and a damascene interconnect structure with higher dimensional accuracy and reliability can be obtained after the metal filling process is carried out, in spite of the feature sizes continue to shrink.

### BRIEF DESCRIPTION OF THE DRAWINGS

The above objects and advantages of the present invention will become more readily apparent to those ordinarily skilled in the art after reviewing the following detailed description and accompanying drawings, in which:

FIGS. 1A to 1F illustrate cross sectional views of a series of processing structures for fabricating a single damascene interconnect structure in accordance with one embodiment of the present invention; and

FIGS. 2A to 2H illustrate cross sectional views of a series of processing structures for fabricating a dual damascene interconnect structure in accordance with another embodiment of the present invention.

### DETAILED DESCRIPTION OF PREFERRED EMBODIMENTS

A method for fabricating a damascene opening is provided by the present invention to form a damascene interconnect structure with higher dimensional accuracy and reliability. The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

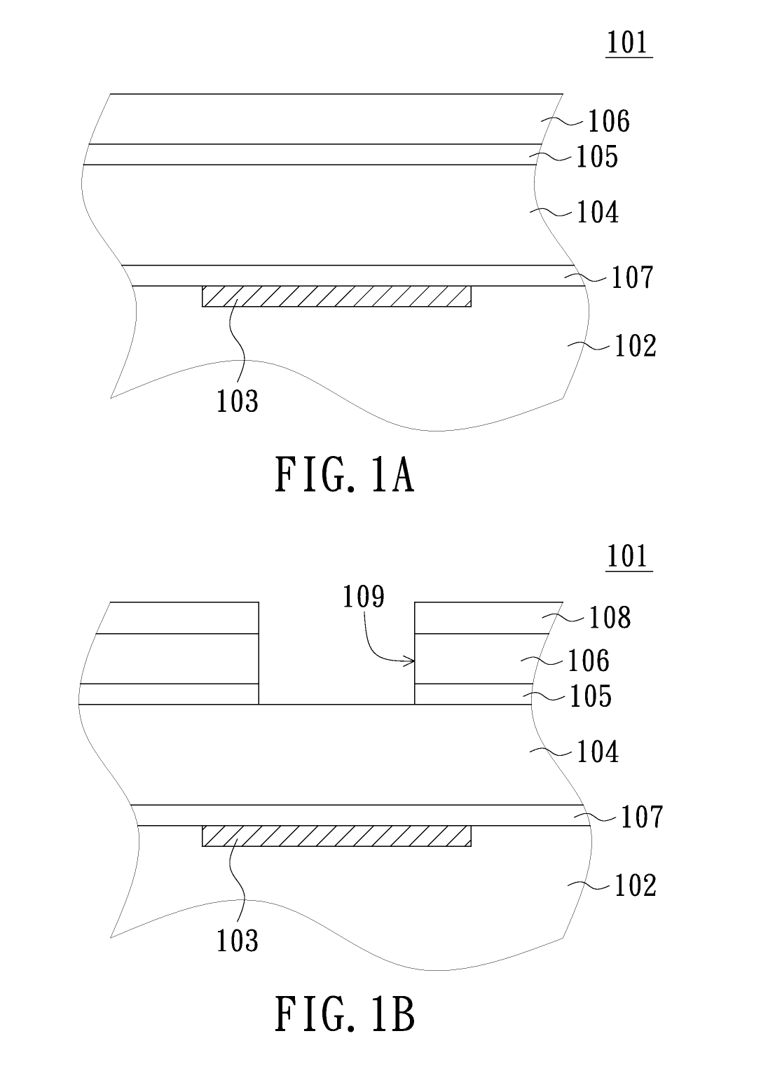

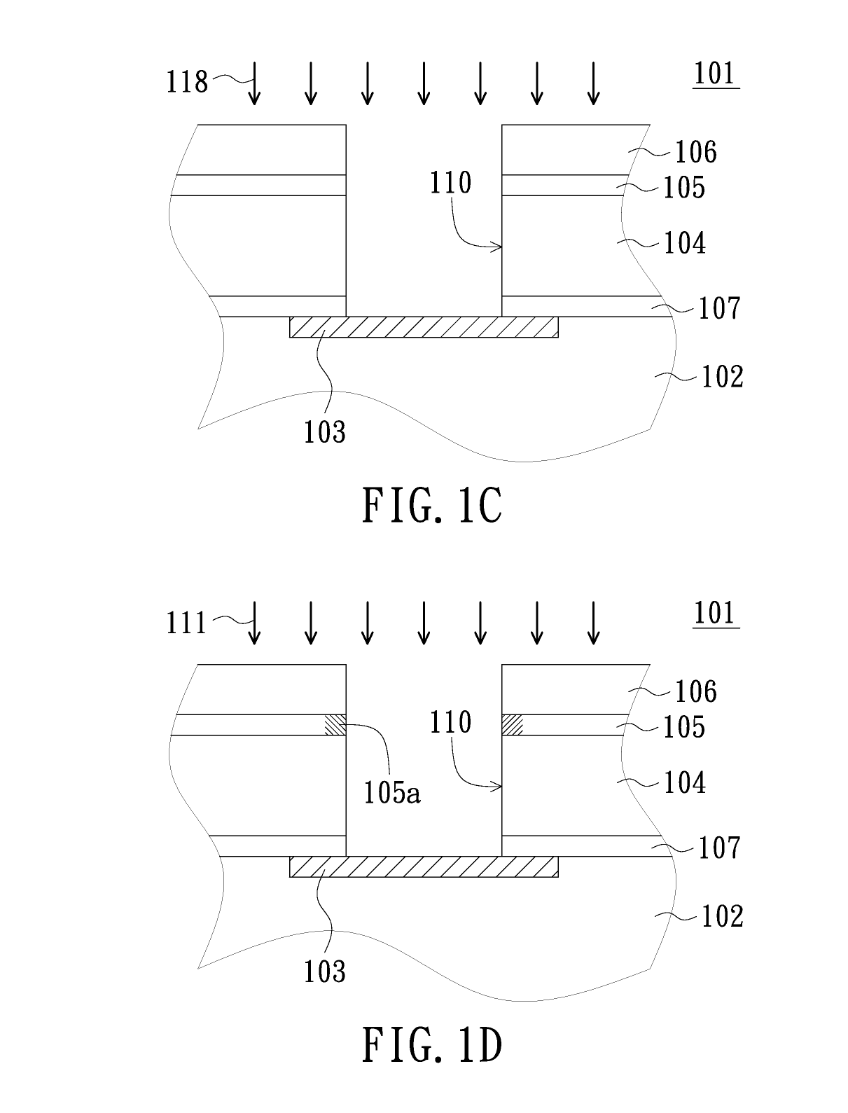

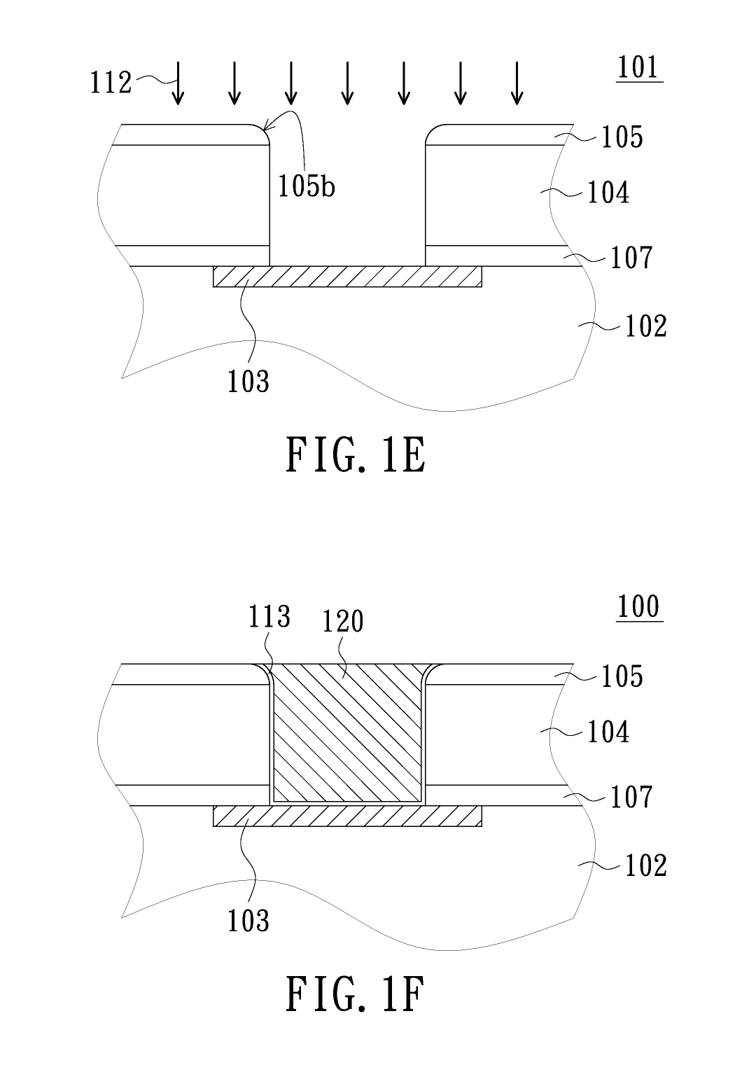

FIGS. 1A to 1F illustrate cross sectional views of a series of processing structures for fabricating a single damascene interconnect structure 100 in accordance with one embodiment of the present invention. The method for fabricating the single damascene interconnect structure 100 comprises steps as follows:

Firstly, a semiconductor structure 101 comprising a conductive layer 103, an IMD 104, a first hard mask layer 105 and a second hard mask layer 106 stacked in sequence over a substrate 102 is provided (see FIG. 1A). In some embodiments of the present invention, the substrate 102 preferably is a silicon substrate, or a silicon substrate having a dielectric material formed thereon. The conductive layer 103 may be a metal layer. The IMD 104 is preferably made of low dielectric constant materials, such as fluorinated silicate glass (FSG), organosilicate glass (OSG) or other ultralow-k (ULK) materials. The IMD 104 can be a composite layer made of multiple dielectric materials, for example, an upper portion of the IMD 104 can be made of silicon oxynitride (SiON) and a lower portion of the IMD 104 can be made of low dielectric constant material. The first hard mask layer 105 may be a Ti layer, and the second hard mask layer 106 is a TiN layer.

In some embodiments of the present invention, the first hard mask layer 105 has a thickness substantially ranging from 50 Å to 300 Å, and the second hard mask layer 106 has a thickness substantially ranging from 100 Å to 300 Å. In a preferred embodiment of the present invention, the first hard mask layer 105 and the second hard mask layer 106 have a total thickness about 300 Å. In the present embodiment, the first hard mask layer 105 has a thickness about 50 Å, and the second hard mask layer 106 has a thickness about 250 Å.

In some preferred embodiments, there is a bottom layer 107 formed on the conductive layer 103 prior to the forming of the IMD 104. The bottom layer 107 is preferably made of a dielectric layer with a lower etching rate than the IMD 104, such as silicon nitride (SiN) or silicon carbon nitride (SiCN), so as to serve as an etching stop layer during trench-etching process of the IMD 104.

Next, the first hard mask layer 105 and the second hard mask layer 106 are patterned using a patterned photo-resist layer 108 serving as an etching mask to form at least one trench opening 109, so as to expose a portion of the IMD 104 (see FIG. 1B). Optionally, the patterned photo-resist layer 108 may be removed by a conventional ash process.

Subsequently, a trench-etching process 118 is performed using the patterned first hard mask layer 105 and the patterned second hard mask layer 106 serving as an etching mask to form a trench 110 extending downwards from the second hard mask layer 106 to the IMD 104. In the present embodiment, as shown in FIG. 1C, the trench 110 formed in the semiconductor structure 101 extends from the patterned second hard mask layer 106 and passing through the first hard mask layer 105, the IMD 104 and the bottom layer 107, whereby a portion of the conductive layer 103 is exposed. In some embodiments of the present invention, the trench-etching process 118 preferably is a plasma-based dry etching process.

A plasma treatment 111 is then performed to modify a portion of the first hard mask layer 105 that is exposed from the trench 110, so as to form a plasma-modified portion 105a in the first hard mask layer 105 (see FIG. 1D). In some embodiments of the present invention, the plasma treatment 111 comprises a reaction gas selected from a group consisting of O₂, CHF₃, CH₂F₂, CH₃F, CF₄ and arbitrary combinations thereof. In one embodiment of the present invention, the reaction gas comprises O₂, and the plasma-modified portion 105a of the first patterned hard mask layer 105 comprises titanium oxide (TiO). In another embodiment of the present invention, the reaction gas comprises CF₄, and the plasma-modified portion 105a of the first patterned hard mask layer 105 comprises titanium fluoride (TiF). In the present embodiment, the plasma-modified portion 105a of the first patterned hard mask layer 105 is composed of TiO.

Subsequently, a wet treatment 112 is performed to remove the second hard mask layer 106 (see FIG. 1E).

In some embodiments of the present invention, the wet treatment 112 comprises steps of using an agent containing heterocyclic compound to remove the second hard mask layer 106. In the present embodiment, an agent, EKC™ 580 Cusolve™ provided by EKC Technology, Inc., part of DuPont Electronics and Communications, serving as an effective copper (Cu) corrosion inhibitor and having a high etching selectivity of TiN over Cu is applied to remove the second hard mask layer 106 and a portion of the first hard mask layer 105 during the wet treatment 112. In the present embodiment, the second hard mask layer 106 that is made of TiN is removed by the EKC™ 580 Cusolve™ agent with an etching rate ranging from 1 angstrom/minute (Å/min) to 250 Å/min; and the first hard mask layer 105 that is made of Ti is removed by the EKC™ 580 Cusolve™ agent with an etching rate substantially less than 1 Å/min during the wet treatment 112.

However, it should be appreciated that, since the plasma-modified portion 105a of the first hard mask layer 105 is made of TiO or TiF which has a removing rate substantially less than that of the TiN layer and less than that of the Ti layer in the EKC™ 580 Cusolve™ agent, thus while the second hard mask layer 106 is being removed by the wet treatment 112, the plasma-modified portion 105a of the first hard mask layer 105 can prevent the remaining portion of the first hard mask layer 105 that is composed of Ti from being exposed by the trench 110 and being unduly etched in the EKC™ 580 Cusolve™ agent. As a result, after the second hard mask layer 106 is removed, a rounding profile 105b of the first hard mask layer 105 can be defined at the edge of the trench 110.

In some embodiments of the present invention, the wet treatment 112 further comprises steps of cleaning the trench 110. In the present embodiment, after the rounding profile 105b of the first hard mask layer 105 is defined, de-ionized (DI) water is applied to remove the residue remaining on the surface of the first hard mask layer 105 and the sidewalls of the trench 110.

Thereinafter, a metal filling process is performed. A metal deposition, electroplate or other suitable technology may be applied to fill a conductive material into the trench 110, so as to form a metal interconnect line 120 that provides an interconnection between the conductive layer 103 and other integrated circuits in a semiconductor device. In some embodiments of the present invention, the conductive material may be Al or Cu. In the present embodiment, a Cu seed deposition is performed to form a Cu seeding layer 113 on the sidewalls of the trench 110 and a portion of the conductive layer 103 exposed from the trench 110 prior to the steps of filling conductive material into the trench 110. After some suitable back end processes (not shown) are performed, the single damascene interconnect structure 100 as shown in FIG. 1F is completed.

In comparison with prior arts, because the second hard mask layer 106 is removed prior to a subsequent metal filling process, the aspect ratio (depth/width) of the trench 110 can be reduced. In addition, the rounding profile 105b of the first hard mask layer 105 can provide the trench 110 with a flared opening to prevent Cu seed from being deposited overhead around the opening of the trench 110. Besides, the rounding profile 105b of the first hard mask layer 105 contributes to the conformal deposition of the Cu seeding layer 113. Thus, it is benefit to the metal filling process. As a result, the single damascene interconnect structure 100 can provide higher dimensional accuracy and reliability than that of the prior arts or conventional damascene interconnect structure with the same requisite feature dimension.

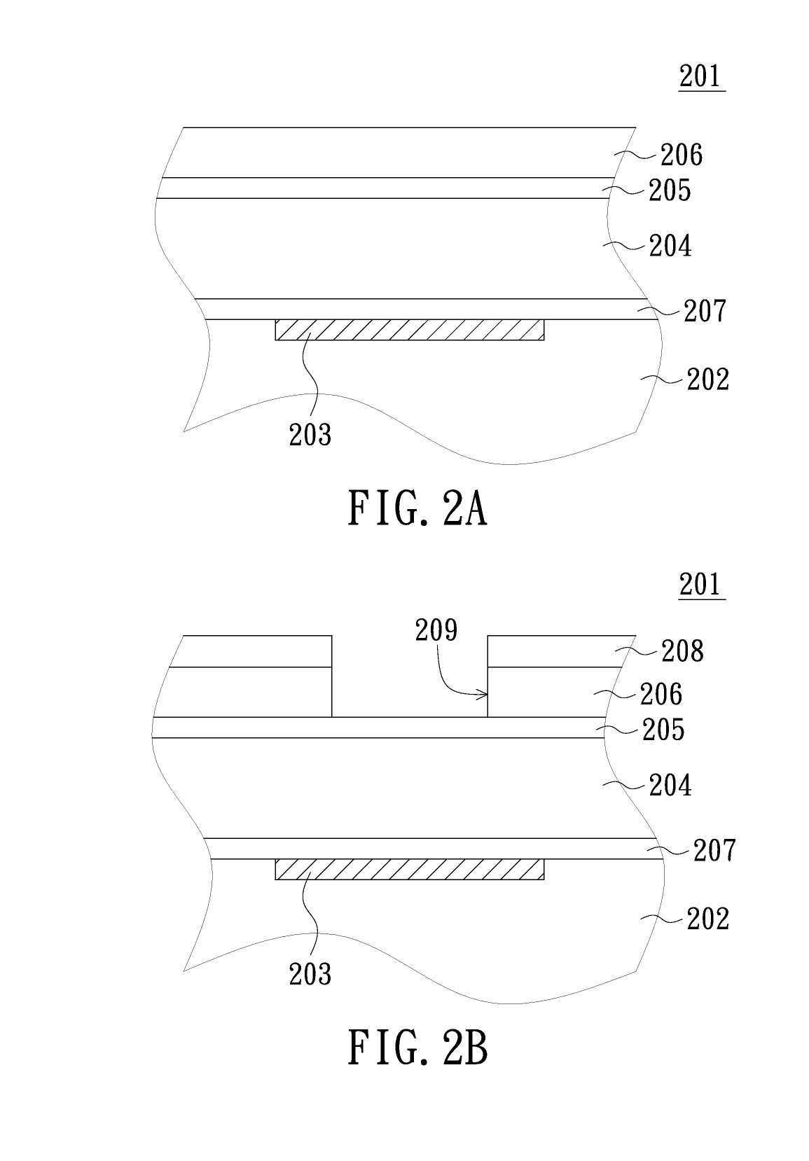

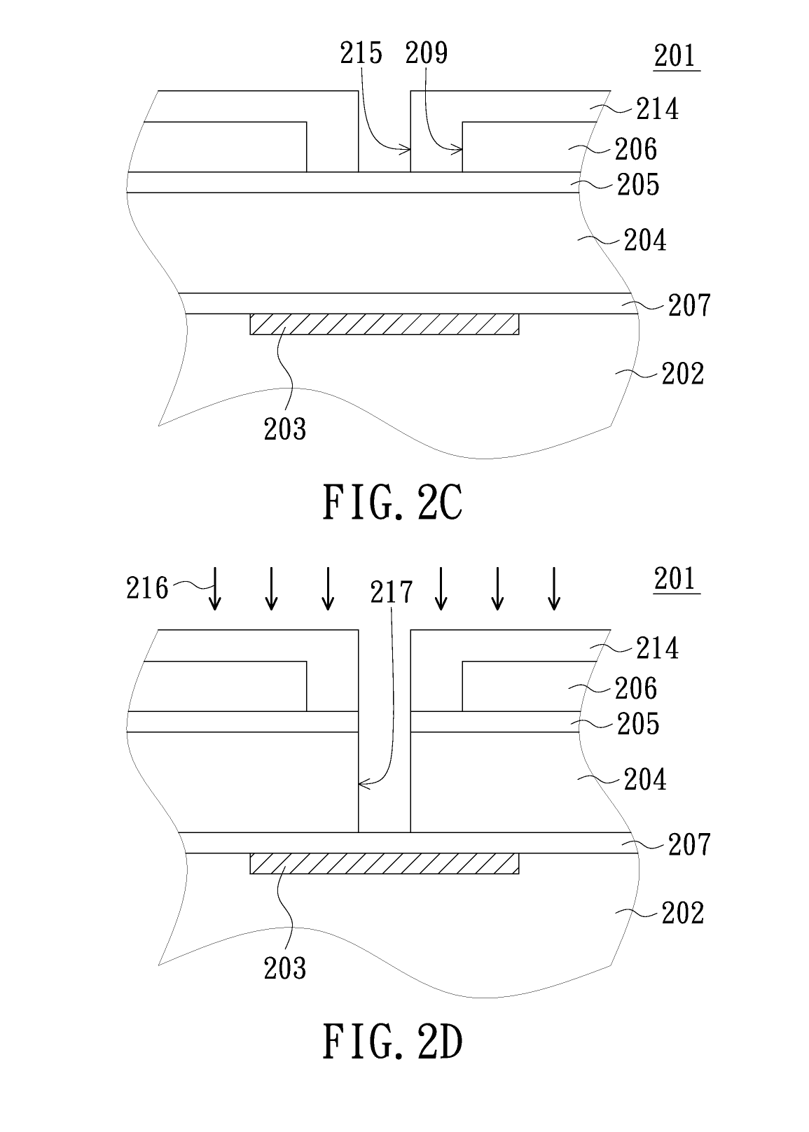

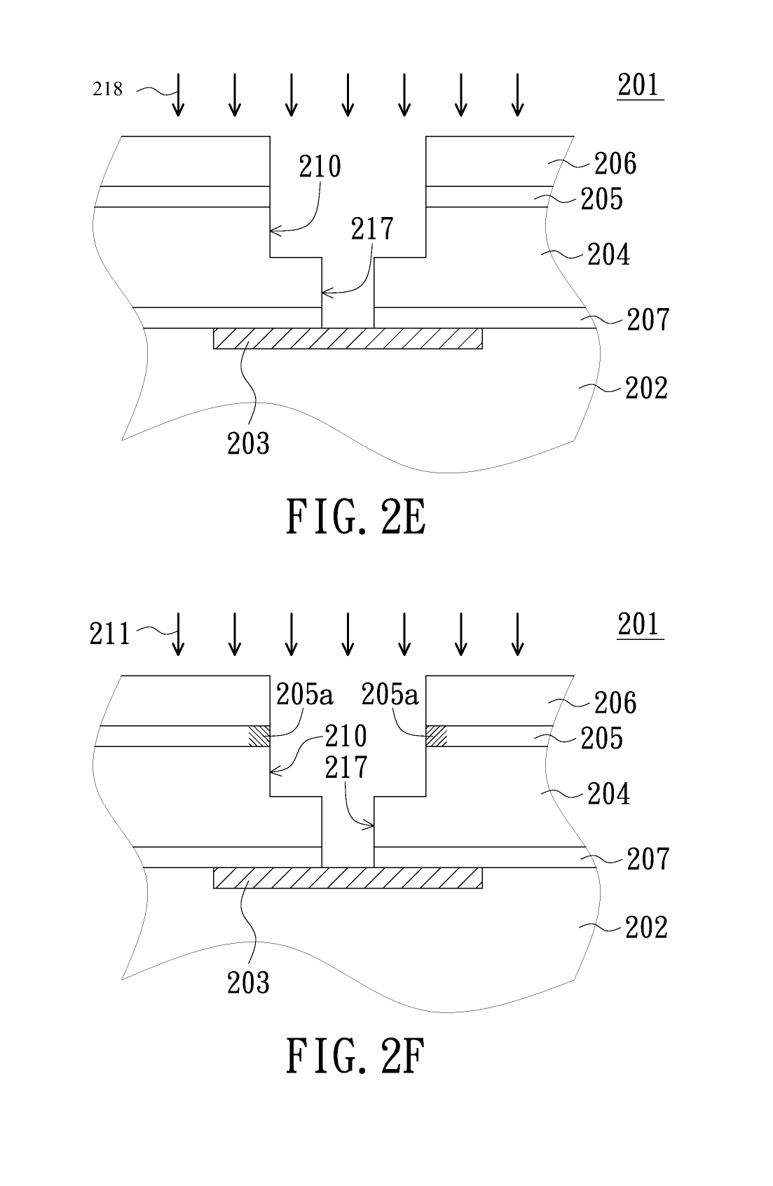

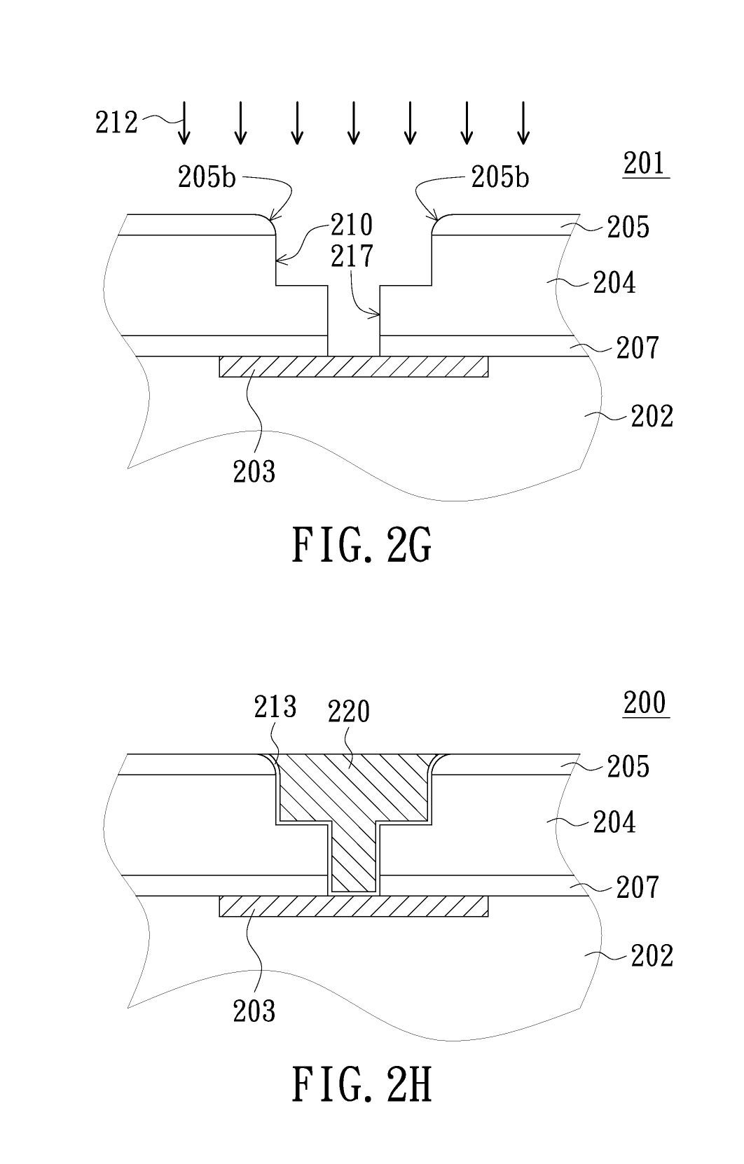

FIGS. 2A to 2H illustrate cross sectional views of a series of processing structures for fabricating a dual damascene interconnect structure 200 in accordance with another embodiment of the present invention. The method for fabricating the dual damascene interconnect structure 200 comprises steps as follows:

Firstly, a semiconductor structure 201 comprising a conductive layer 203, an IMD 204, a first hard mask layer 205 and a second hard mask layer 206 stacked in sequence over a substrate 202 is provided (see FIG. 2A). The substrate 202 preferably is a silicon substrate, or a silicon substrate having a dielectric material formed thereon; the conductive layer 203 is a metal layer. The IMD 204 is preferably made of low dielectric constant materials, such as FSG, OSG or other ULK materials. The IMD 204 can be a composite layer made of several dielectric materials, for example an upper portion of the IMD 204 can be made of silicon oxynitride (SiON) and a lower portion of IMD 204 can be made of low dielectric constant material. The first hard mask layer 205 is a Ti layer, and the second hard mask layer 206 is a TiN layer.

In some embodiments of the present invention, the first hard mask layer 205 has a thickness substantially ranging from 50 Å to 300 Å, and the second hard mask layer 206 has a thickness substantially ranging from 100 Å to 300 Å. In a preferred embodiment of the present invention, the first hard mask layer 205 and the second hard mask layer 206 have a total thickness about 300 Å. In the present embodiment, the first hard mask layer 205 has a thickness about 50 Å, and the second hard mask layer 206 has a thickness about 250 Å.

In some preferred embodiments, there is a bottom layer 207 formed on the conductive layer 203 prior to the forming of the IMD 204. The bottom layer 207 is preferably made of a dielectric layer with a lower etching rate than the IMD 204, such as SiN or SiCN, so as to serve as an etching stop layer during trench-etching process of the IMD 204.

Next, the second hard mask layer 206 is patterned using a patterned photo-resist layer 208 serving as an etching mask to form at least one trench opening 209 in the second hard mask layer 206, so as to expose a portion of the first hard mask layer 205 (see FIG. 2B).

After the photo-resist layer 208 is striped, a patterned photo-resist layer 214 is then formed on the second hard mask layer 206 to fill the trench opening 209, wherein the patterned photo-resist layer 214 has at least one via opening 215 aligning to the trench opening 209, so as to expose a portion of the first hard mask layer 205 (see FIG. 2C).

Next, a via-etching process 216 is performed using the patterned photo-resist layer 214 serving as an etching mask to form a via hole 217 passing through the first hard mask layer 205 and the IMD layer 204, so as to expose a portion of the bottom layer 207 (see FIG. 2D).

Subsequently, a trench-etching process 218 is performed using the patterned second hard mask layer 206 as an etching mask to form a trench 210 extending downwards from the second hard mask layer 206 to the IMD 204. In addition, the portion of the bottom layer 207 exposed from the via hole 217 may be etched through by the trench-etching process 218, as a result, a portion of the conductive layer 203 is exposed from the via hole 217 (see FIG. 2E). In the embodiments of the present invention, the trench-etching process 218 preferably is a plasma-based dry etching process.

A plasma treatment 211 is then performed to modify a portion of the first hard mask layer 205 that is exposed from the trench 210, so as to form a plasma-modified portion 205a in the first hard mask layer 205 (see FIG. 2F). In some embodiments of the present invention, the plasma treatment 211 comprises a reaction gas selected from a group consisting of O₂, CHF), CH₂F₂, CH₃F, CF₄ and arbitrary combinations thereof. In one embodiment of the present invention, the reaction gas comprises O₂, and the plasma-modified portion 205a of the first patterned hard mask layer 205 comprises TiO. In another embodiment of the present invention, the reaction gas comprises CF₄, and the plasma-modified portion 205a of the first patterned hard mask layer 205 comprises titanium fluoride (TiF).

Subsequently, a wet treatment 212 is performed to remove the second hard mask layer 206 (see FIG. 2G).

In some embodiments of the present invention, the wet treatment 212 comprises steps of using an agent containing heterocyclic compound to remove the second hard mask layer 206. In the present embodiment, an agent, EKC™ 580 Cusolve™ provided by EKC Technology, Inc., part of DuPont Electronics and Communications, serving as an effective Cu corrosion inhibitor and having a high etching selectivity of TiN over Cu is applied to remove the second hard mask layer 206 and a portion of the first hard mask layer 205 during the wet treatment 212. In the present embodiment, the second hard mask layer 206 that is made of TiN is removed by the EKC™ 580 Cusolve™ agent with an etching rate ranging from 1 angstrom/minute (Å/min) to 250 Å/min; and the first hard mask layer 205 that is made of Ti is removed by the EKC™ 580 Cusolve™ agent with an etching rate substantially less than 1 Å/min during the wet treatment 212.

However, it should be appreciated that, since the plasma-modified portion 205a of the first hard mask layer 205 is made of TiO or TiF which has a removing rate substantially less than that of TiN and less than that of Ti in the EKC™ 580 Cusolve™ agent, thus while the second hard mask layer 206 is removed by the wet treatment 212, the plasma-modified portion 205a of the first hard mask layer 205 can prevent the remaining portion of the first hard mask layer 205 the is composed of Ti from being exposed by the trench 210 and being unduly etched in the EKC™ 580 Cusolve™ agent. As a result, after the second hard mask layer 206 is removed, a rounding profile 205b of the first hard mask layer 205 can be defined at the edge of the trench 210.

In some embodiments of the present invention, the wet treatment 212 further comprises steps of cleaning the trench 210. In the present embodiment, after the rounding profile 205b of the first hard mask layer 205 is defined, DI water is applied to remove the residue remaining on the surface of the first hard mask layer 205, the sidewalls of the trench 210 and the via hole 217, respectively.

Thereinafter, a metal filling process is performed. A metal deposition, electroplate or other suitable technology is applied to fill a conductive material into the trench 210, so as to form a metal interconnect line 220 or a via plug that provides an interconnection between the conductive layer 203 and other integrated circuits in a semiconductor device. In some embodiments of the present invention, the conductive material may be Al or Cu. In the present invention, a Cu seed deposition is performed to form a Cu seeding layer 213 on the sidewalls of the trench 210 and the portion of the conductive layer 203 exposed from the trench 210 prior to the steps of filling the conductive material into the trench 210. After some suitable or applicable back end processes (not shown) are performed, the single damascene interconnect structure 200 as shown in FIG. 2H is completed.

In comparison with prior arts, because the second hard mask layer 206 is removed prior to a subsequent metal filling process, the aspect ratio (depth/width) of the trench 210 can be reduced. In addition, the rounding profile 205b of the first hard mask layer 205 can provide the trench 210 with a flared opening to prevent Cu seed from being deposited overhead around the opening of the trench 210 and the via hole 217. Besides, the rounding profile 205b of the first hard mask layer 205 contributes to the conformal deposition of the Cu seeding layer 213. Thus, it is beneficial to the metal filling process. As a result, the dual damascene interconnect structure 200 can provide higher dimensional accuracy and reliability than that of the prior arts with the same requisite feature dimension.

In accordance with the aforementioned embodiments of the present invention, two hard mask layers stacked in sequence is applied on an IMD to form a damascene opening therein; a plasma treatment is then performed to modify a portion of the underlying hard mask layer that is exposed from the trench; the upper hard mask layer is removed by a wet treatment prior to a subsequent metal filling process; and a damascene interconnect structure is formed after the metal filling process is carried out.

Since, the plasma-modified portion of the underlying hard mask layer has a removing rate substantially less than a removing rate of the upper hard mask layer in the wet treatment, thus after the upper hard mask layer is removed, a rounding profile of the underlying hard mask layer is defined at the edge of the damascene opening damascene opening. As a result, the damascene opening may have a flared opening that can prevent Cu seed from depositing overhead around the opening of the damascene opening, and a damascene interconnect structure with higher dimensional accuracy and reliability can be obtained after the metal filling process is carried out, in spite of the feature sizes continue to shrink.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A method for forming a damascene opening comprising:
providing a semiconductor structure comprising an inter-metal dielectric (IMD), a first hard mask layer and a second hard mask layer stacked in sequence, wherein the semiconductor structure has at least one trench extending downwards from the second hard mask layer to the IMD;
performing a plasma treatment to modify a portion of the first hard mask layer exposed from the trench to form a plasma-modified portion in the first hard mask layer; and
performing a wet treatment to remove the second hard mask layer and a portion of the first hard mask layer;
wherein the plasma-modified portion of the first patterned hard mask layer has a first removing rate substantially less than a second removing rate of the second hard mask layer in the wet treatment.

2. The method according to claim 1, the process for providing the semiconductor structure further comprises steps of:
forming a conductive layer on a substrate;
forming a bottom layer on the conductive layer;
forming the IMD on the bottom layer;
forming the first hard mask layer on the IMD; and
forming the second hard mask layer on the first hard mask layer;
wherein the second hard mask layer has at least one trench opening for exposing a portion of the first hard mask layer.

3. The method according to claim 2, wherein the process for providing the semiconductor structure further comprises steps of:
forming a photo-resist layer on the second hard mask layer to fill the trench opening;
patterning the photo-resist layer to form a via opening aligning to the trench opening, so as to expose a portion of the first hard mask layer;
performing a via-etching process to form a via hole passing through the first hard mask layer and the IMD layer, so as to expose a portion of the bottom layer; and
performing a trench-etching process using the second hard mask layer as a mask to form the trench and to make the via hole passing through the bottom layer for exposing a portion of the conductive layer.

4. The method according to claim 2, wherein the first hard mask layer is a titanium (Ti) layer, and the second hard mask layer is a titanium nitride (TiN) layer.

5. The method according to claim 4, wherein the first hard mask layer has a thickness substantially ranging from 50 angstrom (Å) to 300 Å.

6. The method according to claim 4, wherein the second hard mask layer has a thickness substantially ranging from 100 Å to 300 Å.

7. The method according to claim 4, wherein the first hard mask layer and the second hard mask layer have a total thickness about 300 Å.

8. The method according to claim 4, wherein the wet treatment comprises steps of using an agent containing heterocyclic compound to remove the second hard mask layer and a portion of the first hard mask layer.

9. The method according to claim 8, wherein the wet treatment further comprises steps of cleaning the trench and the via hole.

10. The method according to claim 8, wherein the TiN layer is removed by the agent with an etching rate ranging from 1 angstrom/minute (Å/min) to 250 Å/min, and the Ti layer is removed by the agent with an etching rate substantially less than 1 Å/min.

11. The method according to claim 4, wherein the plasma treatment comprises a reaction gas selected from a group consisting of oxygen (O₂), CHF₃, CH₂F₂, CH₃F, CF₄ and arbitrary combinations thereof.

12. The method according to claim 11, wherein the reaction gas comprises O₂, and the plasma-modified portion of the first patterned hard mask layer comprises titanium oxide (TiO).

13. The method according to claim 11, wherein the reaction gas comprises CF₄, and the plasma-modified portion of the first patterned hard mask layer comprises titanium fluoride (TiF).

14. A method for fabricating a dual damascene structure, comprising:
providing a semiconductor structure comprising a conductive layer, an IMD, a first hard mask layer and a second hard mask layer stacked in sequence, wherein the semiconductor structure has at least one trench extending downwards from the second hard mask layer and passing trough the first hard mask layer and the IMD to expose the conductive layer;
performing a plasma treatment to modify a portion of the first hard mask layer exposed from the trench to form a plasma-modified portion in the first hard mask layer;
performing a wet treatment to remove the second hard mask layer and a portion of the first hard mask layer, wherein the plasma-modified portion of the first patterned hard mask layer has a first removing rate substantially less than a second removing rate of the second hard mask layer in the wet treatment; and
filling a conductive material into the trench in contact with the exposed conductive layer.

15. The method according to claim 14, further comprising steps of forming a seed layer on sidewalls of the trench and the exposed conductive layer prior to the metal material being filled into the trench.

16. The method according to claim 14, the process for providing the semiconductor structure further comprises steps of:
forming the conductive layer on a substrate;
forming a bottom layer on the conductive layer;
forming the IMD on the bottom layer;
forming the first hard mask layer on the IMD; and
forming the second hard mask layer on the first hard mask layer;
wherein the second hard mask layer has at least one trench opening for exposing a portion of the IMD.

17. The method according to claim 16, wherein the process for providing the semiconductor structure further comprises performing a trench-etching process using the second hard mask layer as a mask to form the trench passing through the IMD layer and the bottom layer for exposing a portion of the conductive layer.
